(19) United States
(12) Patent Application Publication
(10) Pub. No.: US 2004/0022015 A1
(43) Pub. Date: Feb. 5, 2004

(54) Signal plug structure

(76) Inventor: Rung-Hua You, Tu-Cheng City (TW)

Correspondence Address: BRUCE H. TROXELL, SUITE 1404, 5205 LEESBURG PIKE, FALLS CHURCH, VA, 22041, US

(21) Appl. No.: 10/207,881

(22) Filed: Jul. 31, 2002

(51) Int. Cl. H05K 5/00

(52) U.S. Cl. 361/683

(57) ABSTRACT

An improved signal plug used in communication devices, which includes a case, a cover, and a holding groove at the center of the case. The holding groove extends to the back edge of the case, and it has multi-grooved holes on the front end. Cores of the signal cable can be pulled out from the grooved holes on the front end of the case when they are inserted into the case, in order to embed the signal cable in the back opening and the holding grooves of the case to relatively increase the length of exposed twisted cores, to improve the overall signal quality in transmission.

### DESCRIPTION

1. Field of the Invention

This instruction relates generally to an improved signal plug structure, and more particularly, to an improved signal plug structure for communication devices, such as computers and phone lines. On the basis of its special design, the invention can simplify assembly and operation tasks as well as decrease the production cost without degrading signal quality.

2. Background of the Invention

Conventional signal plugs are mainly used in high frequency networks or transmission of phone signals. A typical signal cable 200 used for transmitting signals comprises multi layers of reinforced fibers and other highly conductive materials, covered with an insulation layer. In order to enhance its signal transmission capability and avoid degradation of the signal due to interference or distance in the course of transmission, each two cores 2002 of the cable 200 are twisted together to better transmission result. Modular plugs are the most commonly used ones in signal plugs. When making or assembling a modular plug (see FIG. 1A), the operator shall strip off the exterior insulation layer 2001 of the signal cable 200 in order to expose the twisted cores 2002 of the cable 200. Then, the operator shall insert each core 2002 into the grooved holes 1002 on the holder 100 from the back opening 1001 of the holder 100 (see FIG. 1B), and press the terminal 1003 into the terminal hole 1004 on the holder. As the result, the terminal 1003 electrically contacts with the copper end of cores 2002 to transfer signals. However, that structure has the following shortcomings that shall be overcome in making plugs.

1. Before the cores 2002 are inserted into the corresponding grooved holes 1002 of the holder 100, the twisted cores 2002 should be straightened and smoothed to a certain length, which will degrade the signal.

2. Because the grooved holes 1002 of the holder 100 are half-opened ones, the cores 2002 can only be pushed into them from the back end when inserted. Therefore, the longer the cores 2002 exposed from the insulation layer 2001, the harder the cores can be positioned.

3. Because the cores 200 are difficult to be inserted and positioned accurately into the corresponding grooved holes 1002 of the holder 100, a tool 300 (see FIG. 1B) is needed in application. Thus the steps of assembly and the cost of manufacture are increased to some extent.

Considering above shortcomings of conventional signal plugs, the inventor invented an improved signal plug structure, which is detailed in this document.

### SUMMARY OF THE INVENTION

The main purpose of the present invention is to provide an improved signal plug structure mainly improving the structure of a signal plug used in communication devices, which comprises a case and a cover. There is a holding groove at the center of the case. The holding groove extends to the back edge of the case, and it has multi-grooved holes on the front end. The cores of the signal cable can be pulled out from the grooved holes on the front end of the case when they are inserted into the case, in order to embed the signal cable in the back opening and the holding grooves of the case to relatively increase the length of twisted cores exposed. In this way, the overall signal quality in transmission can be improved.

Another purpose of the present invention is to provide an improved signal plug structure, wherein the holding groove at the center of the case can facilitate the cores to be inserted into the grooved holes without the help of any tool, which also avoids incorrect insertion. This device not only simplifies the assembly process, but also ensures the signal transmission.

The structure, efficacy and principle of the present invention is further detailed in the following illustrations and descriptions.

### BRIEF DESCRIPTION OF THE DRAWINGS

FIG. 1A is a schematic diagram (1) of a conventional signal plug.

FIG. 1B is a schematic diagram of assembly procedures for a conventional signal plug.

FIG. 2 is another schematic diagram (2) of a conventional signal plug.

FIG. 3A is a 3D exploded view (1) of a preferred embodiment implemented according to the present invention.

FIG. 3B is another 3D exploded view (2) of a preferred embodiment implemented according to the present invention.

FIGS. 4A-4C are schematic diagrams of assembly procedures for a preferred embodiment implemented according to the present invention.

FIG. 5 is a sectional diagram of a preferred embodiment implemented according to the present invention.

| | | | |
|---|---|---|---|
| 1 | Case | 11, 1001 | Opening |
| 12, 1002 | Grooved Hole | 13 | Holding Groove |
| 14 | rabbet | 15 | groove |
| 100 | Holder | 1003, 4 | Terminal |
| 16, 1004 | Terminal Hole | 2 | Cover |
| 21 | Hook | 22 | Pressing Bar |
| 23 | Bulgy Bar | 3, 200 | Signal Cable |
| 31, 2001 | Insulating Layer | 32, 2002 | Twisted Cores |
| 300 | Auxiliary Unit | | |

### DETAILED DESCRIPTION OF THE PREFERRED EMBODIMENT

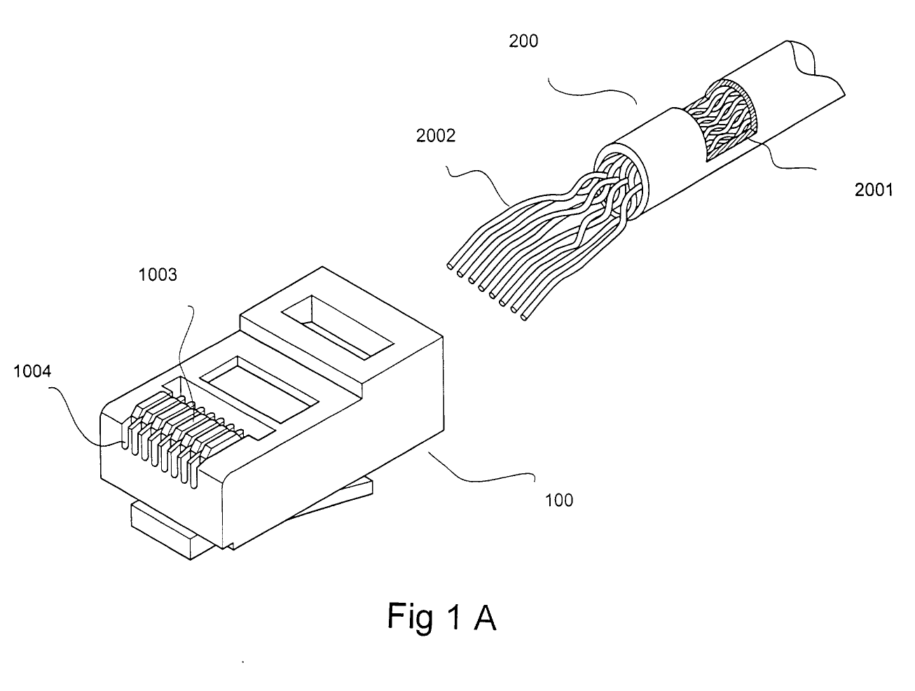

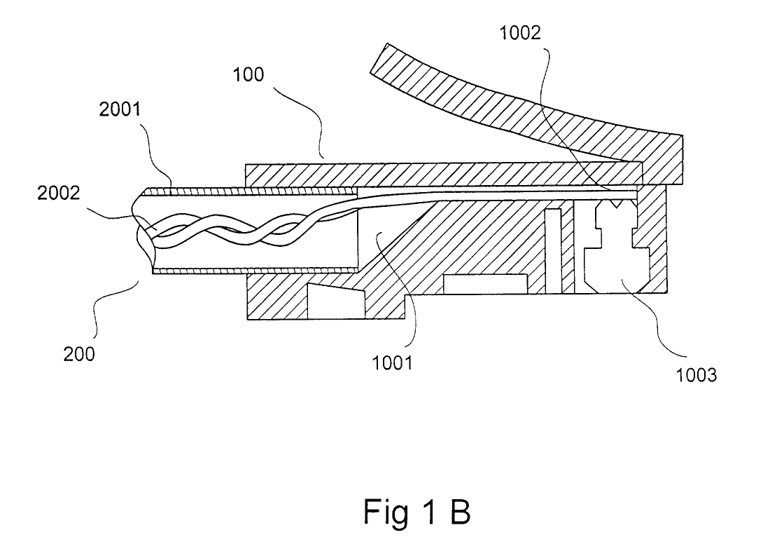

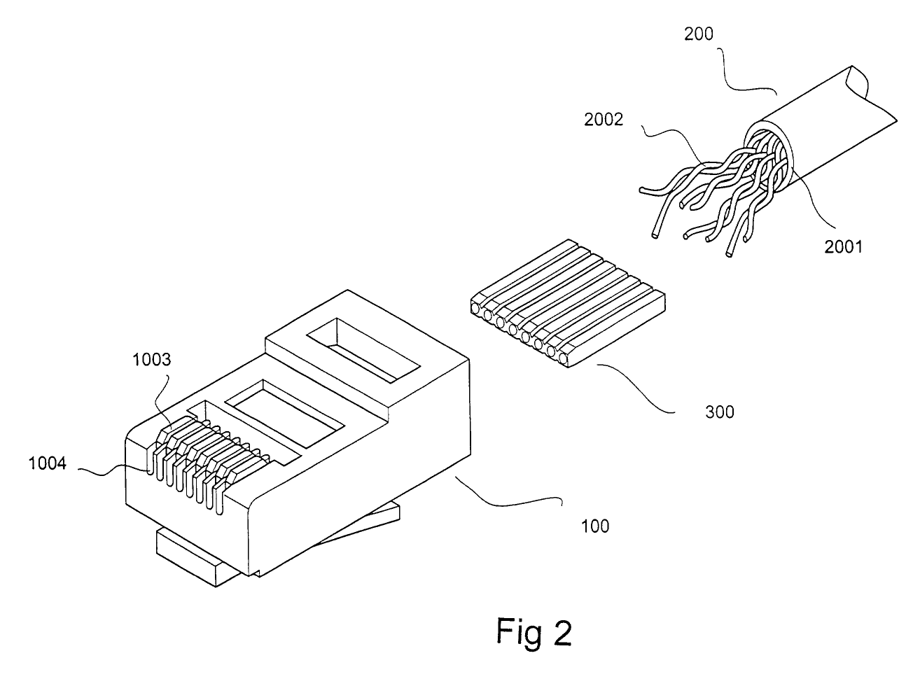

FIGS. 1A, 1B and FIG. 2 are schematic diagrams of conventional signal plugs, and their shortcomings are detailed above.

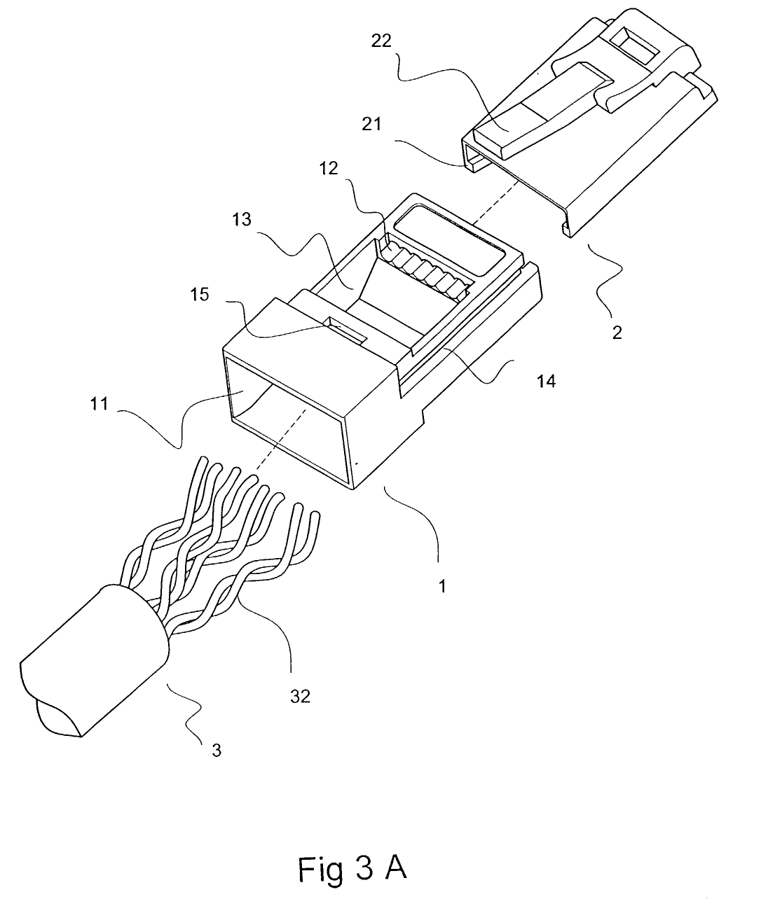

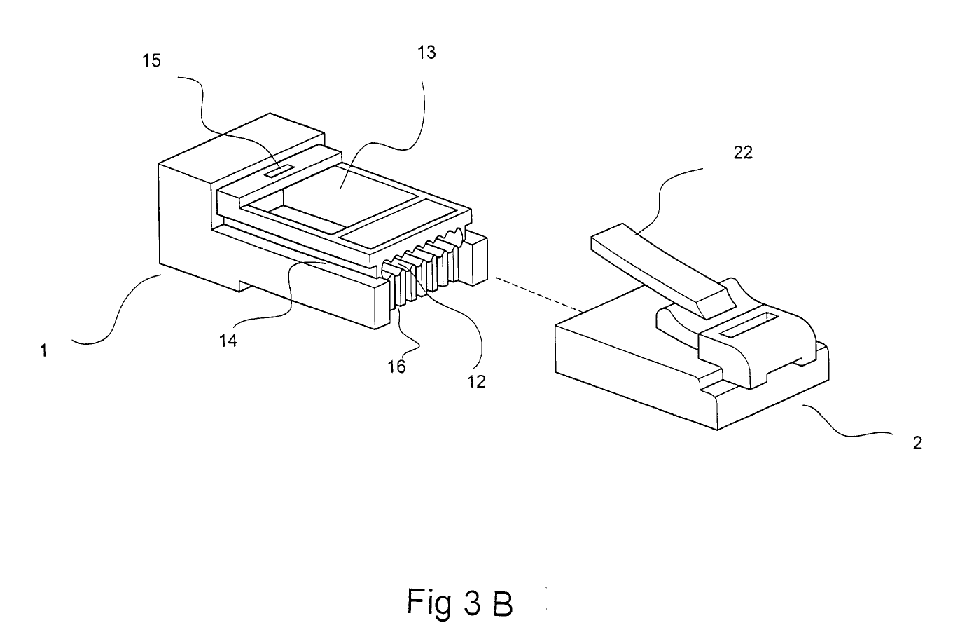

FIG. 3 is a 3D exploded view of a preferred embodiment implemented according to the present invention. Please see also other drawings. From the drawings we can see that the present invention mainly comprises a case 1, a cover 2 and a signal cable 3. The case 1 is made of a type of insulating material. There is a holding groove 13 at the center of the case 1. The holding groove 13 extends to an edge of the case 1 and forms an opening 11 on one end, and it has multi grooved holes 12 at the other end, which are designed to hold the twisted cores (Please see FIG. 3B). There is a rabbet 14 at each side of the case 1. There is a groove 15 on the top of the case 1, and there are a multiple of terminal holes 16 at the bottom of the case 1 to hold the terminals 4. The cover 2 is made of a type of insulating material. There is a hook 21 structure at each side of the cover 2, which can be coupled with the corresponding rabbet 14 at the two sides of the case 1. When coupled, the cover 2 can slide backward or forward along the rabbets 14 on the case 1. There is a bulgy bar 23 on the inner plane of the cover 2, against the groove 15 of the case 1 There is a pressing bar 22 on the top of the cover 2. The signal cable 3 is made of several reinforced fibers and cores 32 twisted together, covered with an insulting layer 31.

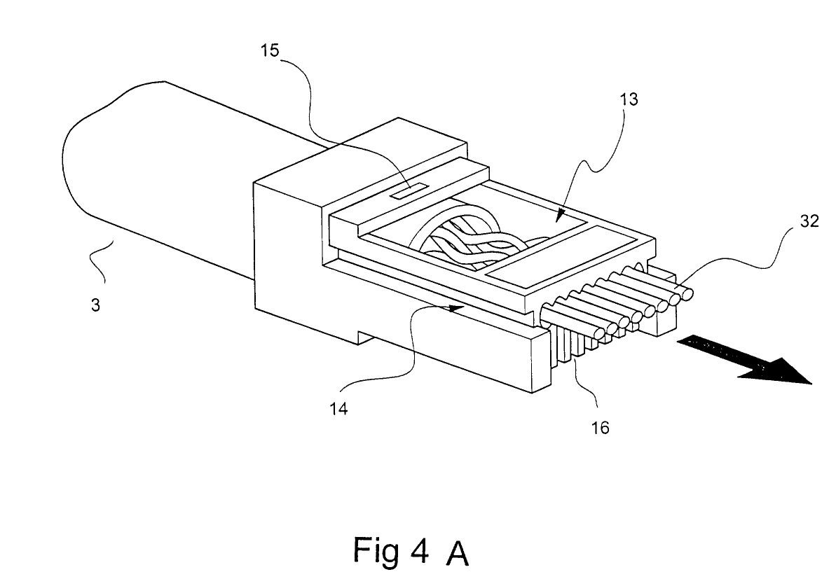

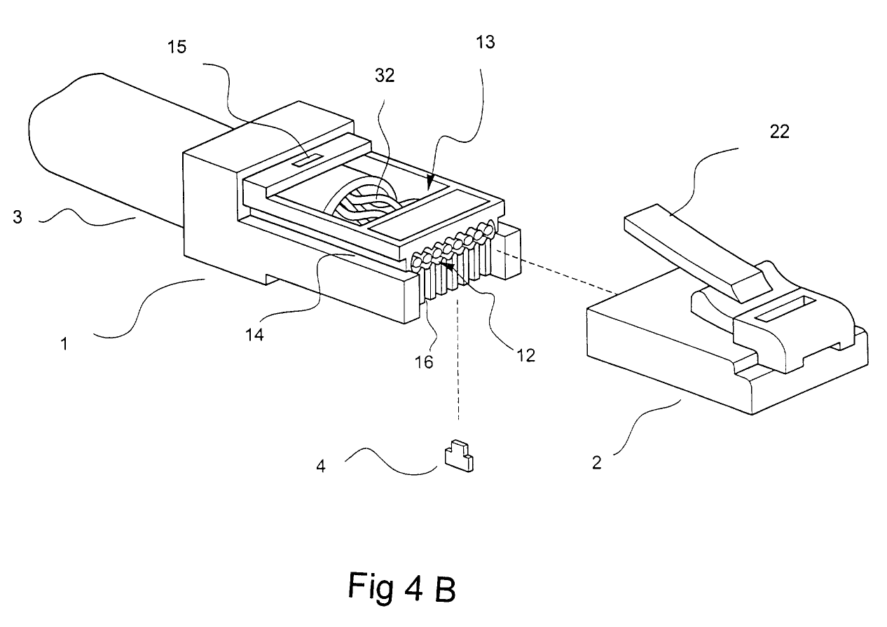

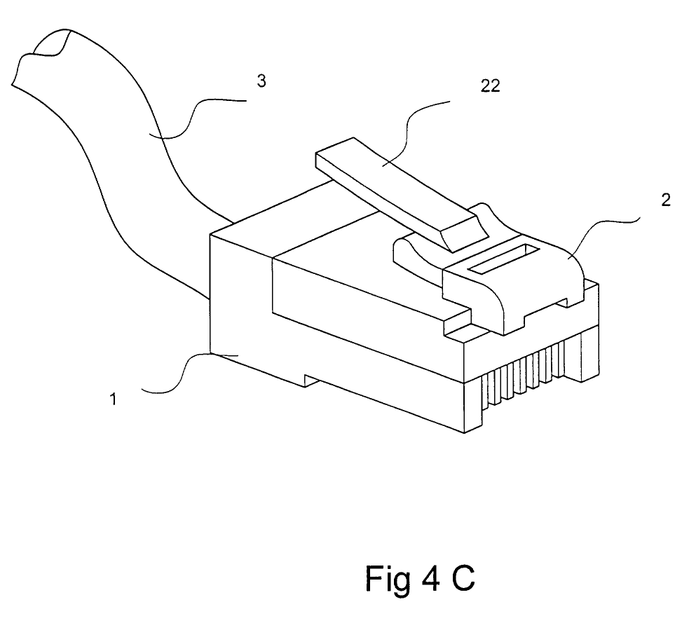

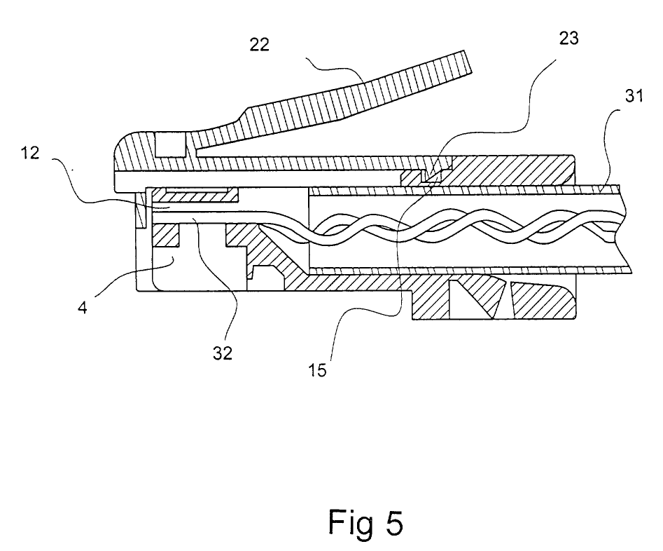

At assembly, a section of the insulting layer 31 around signal cable 3 should be ripped off first to expose the twisted cores 32 in signal cable 3. Then from the opening 11 at the back end of the case 1 (see FIG. 1A), each core 32 should be inserted into the corresponding grooved hole 12 in the case 1 through the holding groove 13 (see FIG. 4A). The holding groove 13 at the center of the case can facilitate the cores 32 to be inserted into the corresponding grooved holes 12 in the case 1 without the help of any tool, which can accelerate the assembly process and also avoid incorrect insertion, The cores 32 can be pulled out from the grooved holes 12 at the frontal end of the case 1 to embed the signal cable 3 in the opening 11 and the holding groove 13 of the case 1. In this way, the twisted length exposed of the cores 32 can be increased, which improves the overall quality of signal transmission. Next, the part of cores 32 extruding out of grooved holes 12 should be cut off (see FIG. 4B), and the terminals 4 should be pressed into the terminal holes 16 in the case 1. When pressed into the terminal holes, the terminals 4 will pierce into the insulating layer of cores 32 and electrically contact the copper leads in the cores 32. Finally, the cover 2 should be fixed on the case 1 through coupling the hooks 21 on the two sides of the cover 2 with the rabbets 14 on the case 1 and locking the bulgy bar 23 on the bottom of the cover 2 into the groove 15 on the case 1 (see FIG. 4C). The bulgy bar 23 on the bottom of the cover 2 employs an inclined plane structure (see FIG. 5) to facilitate the locking with the groove 15 of the case 1.

The improved signal plug structure described above not only simplifies and ease the assembling process and avoiding incorrect insertion when each core is inserted into the corresponding grooved hole 12 of the case 1 without the help of any tool, but also ensure the signal cable 3 to be embedded in the opening 11 and the holding groove 13 of the case 1 through pulling the cores 32 from the grooved holes 12 forward to increase the twisted part of cores 32 exposed, which in turn improve the quality of signals in transmission significantly.

From above description we can see that the improved signal plug structure in the present invention not only simplifies the assembling process and improves the quality of signals in transmission, but also facilitate the cores to be inserted into the plug more easily without the help of any tool. It is the first device with such proven features and meets all requirements for a new patent. Thus the inventor applies for a new patent with it.

Above descriptions are only for a preferred embodiment implemented according to the present invention, and should not constitute any limitation to this invention. Any variant compliant to the following claims should fall into the concept of this invention.

What is claimed is:

1. An improved signal plug structure comprising a case and a cover, wherein at the center of said case a holding groove extends to the back edge of said case to form an opening, and said holding groove has multi grooved holes extending to the front edge of said case; the cores of a signal cable can be inserted into said grooved holes from said opening and can be pulled out to embed said cable in said opening and said holding groove, in order to increase the length of exposed twisted cores to improve the overall quality of signals in transmission.

2. The improved signal plug structure as claim 1, wherein there is a holding groove at the center of said case; said holding groove connects with said opening and said grooved holes and can be used to guide the cores into the grooved holes without the help of any tool and avoid incorrect insertion.

3. The improved signal plug structure as claim 1, wherein there is a groove at each side of the case; the cover has a corresponding hook structure extruding downward at each side, which can be inserted into the said groove on the case; when the hooks and the grooves couple together, the cover can slide forward or backward on the case freely.
